(19) United States
(12) Patent Application Publication
(10) Pub. No.: US 2005/0064662 A1
(43) Pub. Date: Mar. 24, 2005

(54) [METHOD OF FABRICATING FLASH MEMORY]

(76) Inventors: Ling-Wuu Yang, Taichung (TW); Kuang-Chao Chen, Hsinchu (TW); Jui-Lin Lu, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/605,254

(22) Filed: Sep. 18, 2003

(51) Int. Cl. H01L 21/336

(52) U.S. Cl. 438/264

(57) ABSTRACT

A method of fabricating a flash memory. A tunneling dielectric layer, a conductive layer and a mask layer are sequentially formed on a substrate. The mask layer, the conductive layer and the tunneling dielectric layer are patterned to form longitudinally arranged strips on the substrate. Buried drain regions are then formed in the substrate between the strips. The strips are further patterned into floating gate structures. An insulation layer is formed on perimeters of the floating gate structures. The insulation layer has a top surface lower than a top surface of the conductive layer of the floating gate structures, such that a part of sidewalls of the conductive layer is exposed. The mask layer is removed, a gate dielectric layer is formed on the exposed conductive layer, and a control gate is formed on the gate dielectric layer.

### BACKGROUND OF INVENTION

1. Field of the Invention

The invention relates in general to a method of fabricating a flash memory, and more particularly, to a method of a flash memory in which an overlap area between a floating gate and a control gate is increased.

2. Related Art of the Invention

Flash memory has been broadly applied in personal computer and electronic products due to the superior data retention characteristics.

The typical flash memory has a stack-gate structure, which comprises a tunneling oxide layer, a polysilicon floating gate used to store charges, a silicon oxide/silicon nitride/silicon oxide (ONO) dielectric layer, and a polysilicon control gate used to control the data access.

Normally, the larger the gate-coupling ratio (GCR) between the floating gate and the control gate, the lower the operation voltage required. Consequently, operation speed and efficiency are greatly enhanced. The method of increasing the gate-coupling ratio includes increasing the overlap area, or decreasing the thickness of the dielectric layer, or increasing the dielectric constant k of the dielectric layer between the floating gate and the control gate.

As mentioned above, increasing the overlap area between the floating gate and the control gate is advantageous to increasing the gate-coupling ratio. However, due to the continuous demand of higher integration, the area occupied by each memory cell has to be reduced. Therefore, how to fabricate a flash memory with a high gate-coupling rate within limited chip area has become an important task.

### SUMMARY OF INVENTION

The present invention provides a method of fabricating a flash memory in which the overlap area between a floating gate and a control gate is increased, such that the coupling ratio thereof is increased.

The method of fabricating a flash memory provided by the present invention comprises the following steps. A tunneling dielectric layer, a conductive layer and a mask layer are sequentially formed on a substrate. The mask layer, the conductive layer and the tunneling dielectric layer are patterned to form longitudinally arranged strips on the substrate. Buried drain regions are then formed in the substrate between the strips. The strips are further patterned into floating gate structures, which thus comprise the patterned tunneling dielectric layer, the patterned conductive layer and the patterned mask layer. An insulation layer is formed on perimeters of the floating gate structures. The insulation layer has a top surface lower than a top surface of the patterned conductive layer of the floating gate structures, such that a part of the sidewalls of the conductive layer is exposed. The patterned mask layer is removed to expose the top surface of the patterned conductive layer, a gate dielectric layer is formed on the top surface and the exposed sidewalls of the patterned conductive layer, and a control gate is formed on the gate dielectric layer.

In the present invention, the height of the insulation layer formed on perimeters of the floating gates is reduced, such that the gate dielectric layer is formed on both the top surface and the sidewall of the floating gate. As a result, the overlap area between control gate formed on the gate dielectric layer and the floating gate is increased, and the gate-coupling ratio is increased.

### BRIEF DESCRIPTION OF DRAWINGS

These, as well as other features of the present invention, will become more apparent upon reference to the following drawings.

FIGS. 1A to 1G are top views showing the fabrication process of a flash memory according to a preferred embodiment of the present invention.

FIGS. 2A to 2G are cross-sectional views along line I-I″ as shown in FIGS. 1A to 1G, respectively.

### DETAILED DESCRIPTION

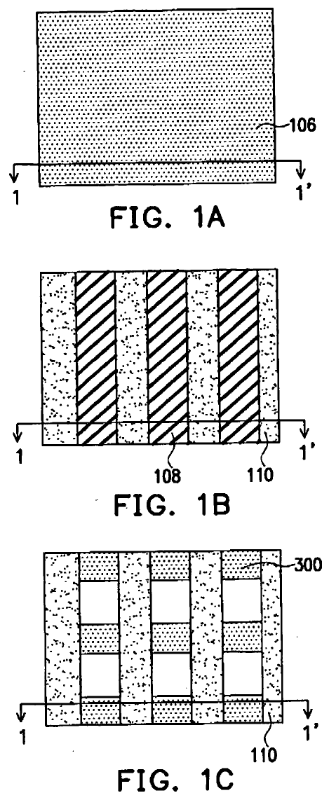

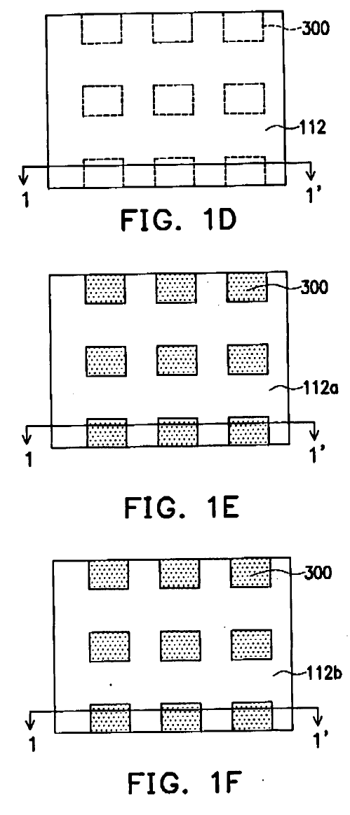

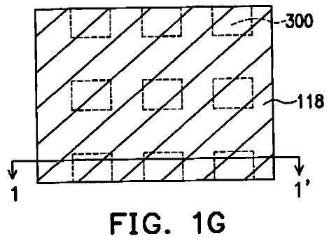

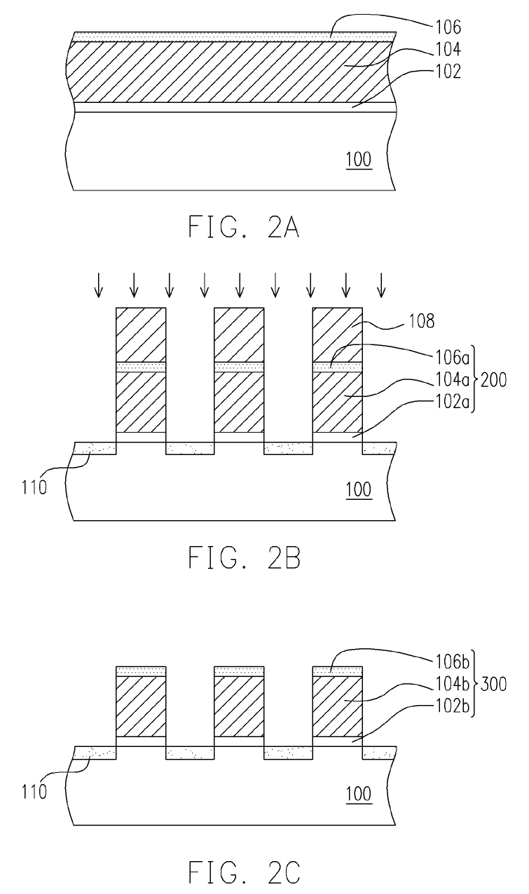

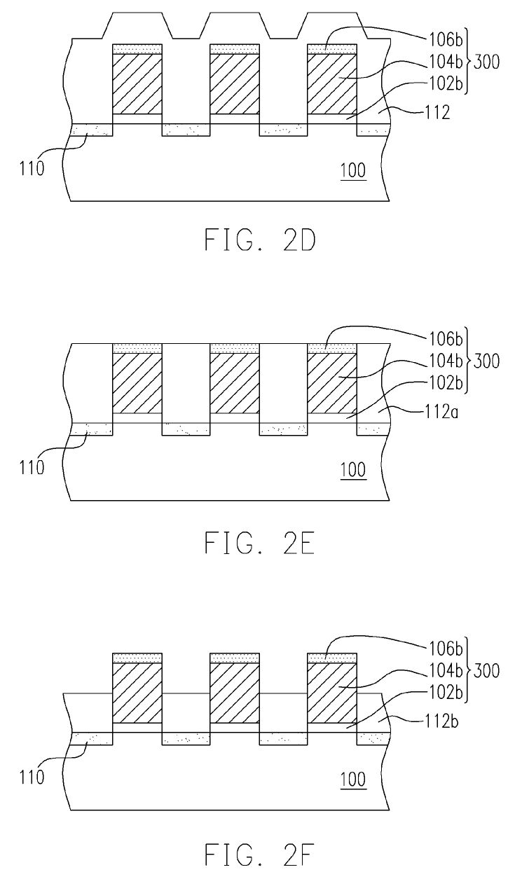

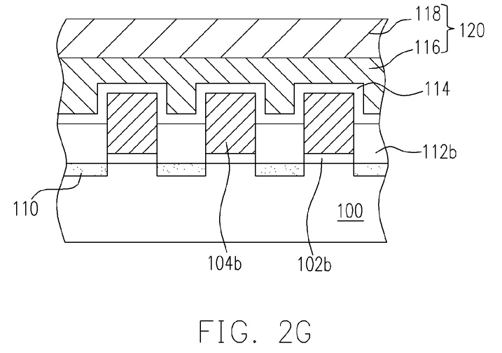

FIGS. 1A to 1G are top views showing the fabrication process of a flash memory according to a preferred embodiment of the present invention. FIGS. 2A to 2G are cross-sectional views along line I-I′ as shown in FIGS. 1A to 1G, respectively. Referring to FIGS. 1A and 2A, a substrate 100 is provided. The substrate 100 includes a silicon substrate, for example. A tunneling dielectric layer 102, a conductive layer 104 and a mask layer 106 are sequentially formed on the substrate 100. The material of the tunneling dielectric layer 102 includes silicon oxide, and the thickness thereof is about 50 angstroms to about 100 angstroms, for example.

The method for forming the tunneling dielectric layer 102 includes thermal oxidation or low-pressure chemical vapor deposition (LPCVD), for example. The material of the conductive layer 104 includes doped silicon formed by low-pressure chemical vapor deposition with silane as a gas source to deposit a polysilicon layer, followed by an dopant implantation process, for example. The operation of the deposition process is about 575° C. to about 650° C., and the operation pressure thereof is about 0.3 torr to about 0.6 torr.

The material of the mask layer 106 includes silicon nitride or silicon oxide formed by low-pressure chemical vapor deposition using dichloro-silane and ammonia as reacting gas.

Referring to FIGS. 1B and 2B, a patterned photoresist layer 108 is formed on the mask layer 106. The mask layer 106, the conductive layer 104 and the tunneling di-electric layer 102 are etched using the patterned photoresist layer 108 as a mask to form a plurality of strips 200 longitudinally arranged on the substrate 100. The strips 200 comprise the patterned tunneling dielectric layer 102a, the patterned conductive layer 104a, and the patterned mask layer 106a. An ion implantation step is performed to form buried drain regions 110 in the substrate between the strips 200.

Referring to FIGS. 1C and 2C, the patterned photoresist layer 108 is removed. Another patterned photoresist layer (not shown) is formed on the strips, and the strips 200 are etched using the patterned photoresist layer as a mask to form the floating gate structures 300. The floating gate structures 300 comprise the patterned tunneling dielectric layer 102b, the patterned conductive layer 104b, and the patterned mask layer 106b. The patterned conductive layer 104b is then used as the floating gate.

Referring to FIGS. 1D and 2D, an insulation layer 112 is formed on the substrate 100 to cover the floating gate structures 300 and fill the spaces between the floating gate structures 300. The material for forming the insulation layer 112 is different from that of the mask layer 106b, including silicon oxide, silicon nitride or spin-on-glass, for example. The method for forming the insulation layer 112 includes high-density plasma chemical vapor deposition (HDP-CVD) or spin-coating, for example.

Referring to FIGS. 1E and 2E, the insulation layer 112 on the mask layer 106b is removed to expose the patterned mask layer 106b. The remaining insulation layer 112 located between the floating gate structures 300 is denoted by a reference numeral 112a. The method for partly removing the insulation layer 112 includes chemical mechanical polishing (CMP) or etch back, for example.

Referring to FIGS. 1F and 2F, a part of the remaining insulation layer 112a is removed to remain the insulation layer 112b with a top surface lower than a top surface of the conductive layer (floating gate) 104b, such that a part of the sidewall of the conductive layer 104b is exposed. The method for partly removing the insulation layer 112a includes etch back, for example.

Referring to FIGS. 1G and 2G, the mask layer 106b is removed to expose the top surface of the conductive layer 104b. The method for removing the mask layer 106b includes wet etching, for example. When the material of the mask layer 106b is silicon nitride, the etchant used in the wet etching step includes phosphoric acid.

A gate dielectric layer 114 is formed over the substrate to cover the top surface and the exposed sidewall of the conductive layer 104b. The material for forming the gate dielectric layer 114 includes silicon oxide/silicon nitride/silicon oxide, for example. The method for forming the gate dielectric layer 114 includes forming an oxide layer by thermal oxidation, followed by low-pressure chemical vapor deposition to form a silicon nitride layer and another silicon oxide layer, for example. The gate dielectric layer 114 may also be made of other materials such as silicon oxide or silicon oxide/silicon nitride.

A conductive layer 120 is formed on the gate dielectric layer 114 as a control gate. The conductive layer 120 includes a polycide layer consisting of a doped polysilicon layer 116 and a silicide layer 118, for example. The method for forming the doped polysilicon layer 116 includes an in-situ doping step. The silicide layer includes a low-pressure chemical vapor deposition using metal fluoride and silane as the gas source, for example. The subsequent process for forming the flash memory is known in the art and is not further described.

Accordingly, as the height of the insulation surrounding the floating gate is reduced, such that the sidewall of the floating gate is partly exposed, resulting in a larger area for forming the gate dielectric layer and for overlapping with the control gate. Consequently, the gate-coupling ratio is enhanced without increasing the cell area of the flash memory, such that the device integration is maintained.

Other embodiments of the invention will appear to those skilled in the art from consideration of the specification and practice of the invention disclosed herein. It is intended that the specification and examples be considered as exemplary only, with a true scope and spirit of the invention being indicated by the following claims.

1. A method of fabricating of a flash memory, comprising:
sequentially forming a tunneling dielectric layer, a conductive layer and a mask layer on a substrate;
patterning the tunneling dielectric layer, the conductive layer and the mask layer to form a plurality of strips;
performing an ion implantation step to form a buried drain region in the substrate between the strips;
forming an insulation layer between the strips such that a top surface of the insulation layer is between a lower surface and a top surface of the patterned conductive layer such that a part of a sidewall of the patterned conductive layer is exposed;
removing the patterned mask layer;
forming a gate dielectric layer on the top surface and the exposed sidewall of the patterned conductive layer; and
forming a control gate on the gate dielectric layer.

2. The method according to claim 1, wherein the step of forming the insulation layer between the strips further comprises:
forming an insulation material layer on the substrate to cover the strips and fill space between the strips;
removing a part of the insulation material layer that covers the the strips until the patterned mask layer is exposed; and
removing a part of the reining Insulation layer until the top surface of the remaining insulation material layer is between a top surface and a bottom surface of the patterned conductive layer.

3. The method according to claim 2, wherein the insulation material layer comprises silicon oxide, silicon nitride, or spin-on glass.

4. The method according to claim 2, wherein the insulation material layer is formed by using high-density plasma chemical vapor deposition process.

5. The method according to claim 4, wherein the high-density plasma chemical vapor deposition process is carried out using tetra-ethyl-oxy-silicate and ozone.

6. The method according to claim 2, wherein the step of removing the part of the insulation material layer is accomplished using a chemical mechanical or etch back process.

7. The method according to claim 2, wherein the step of removing the part of the remaining insulation material layer is accomplished using an etch back process.

8. The method according to claim 1, wherein the mask layer comprises silicon oxide or silicon nitride.

9. The method according to claim 1, wherein the step of removing the patterned mask layer is accomplished by using wet etching process.

10. The method according to claim 9, wherein the wet etch process is carried out using phosphoric acid as etchant when the mask layer comprises silicon nitride.

11. A method of fabricating a flash memory, comprising:
forming a tunneling dielectric layer and a floating gate on a substrate;
performing an ion implantation step to form a buried drain region in the substrate between the floating gates; and
forming an insulation layer between the floating gates after forming the floating gates;
removing a portion of the insulation layer such that a top surface of the insulation layer is located between a top surface and a bottom surface of the floating gates;
forming a gate dielectric layer over the top surface and the exposed sidewalls of the floating gates; and
forming a control gate on the gate dielectric layer.

12. The method according to claim 11, wherein the step of forming the insulation layer further comprises:
forming an insulation material layer on the substrate to cover the floating gates and fill space between the floating gates;
removing a part of the insulation material layer that covers the floating gates to expose the top surface of the floating gates; and
removing a part of the remaining insulation material layer until the top surface of the insulation material layer is between the top surface and the bottom surface of the floating gates.

13. The method according to claim 12, wherein the insulation material layer comprises silicon oxide.

14. The method according to claim 13, wherein the step of forming the insulation material layer is carried out by using high-density plasma chemical vapor deposition process.

15. The method according to claim 14, wherein the high-density plasma chemical vapor deposition process is carried out using tetra-ethyl-oxy-silicate and ozone.

16. The method according to claim 12, the step of removing the part of the insulation material layer is accomplished by using chemical mechanical or etch back process.

17. The method according to claim 11, further comprising a step of forming a patterned mask layer on the floating gates.

18. The method according to claim 18, wherein the patterned mask layer is removed during the step of removing the part of the insulation material layer using a wet etching process.

19. The method according to claim 12, wherein the step of removing the part of the remaining insulation material layer is accomplished by using an etch back process.
